(19) United States
(12) Patent Application Publication
(10) Pub. No.: US 2025/0287515 A1
(43) Pub. Date: Sep. 11, 2025

(54) ELECTRONIC CONTROL UNIT

(71) Applicant: YAZAKI CORPORATION, Tokyo (JP)

(72) Inventors: Koki ADACHI, Shizuoka (JP); Ryo HAMADA, Shizuoka (JP)

(73) Assignee: YAZAKI CORPORATION, Tokyo (JP)

(21) Appl. No.: 19/069,442

(22) Filed: Mar. 4, 2025

(30) Foreign Application Priority Data
Mar. 11, 2024 (JP) 2024-036555

(51) Int. Cl. H05K 5/00; B60R 16/023

(52) U.S. Cl. CPC H05K 5/0026; B60R 16/0231

(57) ABSTRACT

An electronic control unit includes a substrate on which electronic components are mounted; a plurality of terminals having first ends connected to the substrate; a plurality of electric wires having a first end portion connected to one of second ends of the plurality of terminals on an opposite side to the first ends; and a routing board having a base in a shape of a plate, arranged in parallel with the substrate. The routing board routes the plurality of electric wires introduced from outside on a routing surface of the base opposite to a back surface facing the substrate. The second ends of at least one of the terminals are located between the base and the substrate. The base has an opening partially facing the terminals having the second ends located between the base and the substrate and introducing the electric wires.

### CROSS REFERENCE TO RELATED APPLICATION

The present application is based on, and claims priority from the Japanese Patent Application No. 2024-036555, filed on Mar. 11, 2024, the entire contents of which are incorporated herein by reference.

### TECHNICAL FIELD

The present disclosure relates to an electronic control unit.

### BACKGROUND

Conventionally, vehicles such as automobiles are equipped with an electronic control unit used for controlling various functions. In general, the electronic control unit includes a substrate on which electronic components are mounted. As an example of such a substrate, JP 2002-58129 A discloses a technology related to an electrical connection box including a wiring board having a plurality of reinforcing projections for supporting male terminals for fuse connections.

### SUMMARY OF THE INVENTION

On a substrate such as a wiring board disclosed in JP 2002-58129 A, a configuration in which an electric wire is connected to a terminal having one end joined to the substrate can also be considered. When a plurality of electric wires are routed on a substrate, a routing board arranged in parallel with the substrate is further provided, a plurality of electric wires are routed on the routing board, and end portions of the electric wires may be connected to a part of a terminal exposed on the routing board in advance. However, when, for example, a plurality of terminals exposed on the routing board are randomly arranged, and a large number of electric wires are intermingled on a routing board, there is room for improvement in order to increase degrees of freedom for wiring.

An object of the present disclosure is to provide an electronic control unit inside of which degrees of freedom for wiring are increased.

An electronic control unit according to an aspect of an embodiment includes a substrate on which electronic components are mounted; a plurality of terminals having first ends connected to the substrate; a plurality of electric wires having a first end portion connected to one of second ends of the plurality of terminals on an opposite side of the first ends; and a routing board having a base in a shape of a plate, arranged in parallel with the substrate; in which the routing board routes the plurality of electric wires introduced from outside on a routing surface of the base opposite to a back surface facing the substrate; the second ends of at least one of the terminals are located between the base and the substrate; and the base has an opening partially facing the terminals having the second ends located between the base and the substrate and used for introducing the electric wires.

According to the configuration above, it is possible to provide an electronic control unit which increases degrees of freedom for wiring therein.

### BRIEF DESCRIPTION OF THE DRAWINGS

FIG. 1 is a perspective view of an electronic control unit according to one embodiment.

FIG. 2 is a perspective view of a circuit unit included in the electronic control unit.

FIG. 3 is an enlarged perspective view of electric wire connections corresponding to part III of FIG. 2.

FIG. 4 is a plan view of a circuit unit including an example of wiring on a routing board.

FIG. 5 is an enlarged plan view of the electric wire connections corresponding to part V in FIG. 4.

FIG. 6 is a side view of the electric wire connections corresponding to a cross section VI-VI in FIG. 5.

FIG. 7 is a cross-sectional view of the electric wire connections corresponding to a cross section VII-VII in FIG. 5.

FIG. 8 is a side view of the electric wire connections corresponding to a cross section VIII-VIII in FIG. 5.

FIG. 9 is a cross-sectional view of the electric wire connection corresponding to a cross section IX-IX in FIG. 5.

### DETAILED DESCRIPTION OF THE INVENTION

Hereinafter, an electronic control unit according to one embodiment will be described in detail with reference to the drawings. Hereinafter, the term “electronic control unit” will be abbreviated as “ECU.” The dimensional ratios in the drawings are exaggerated for the sake of explanation and may differ from the actual ratios.

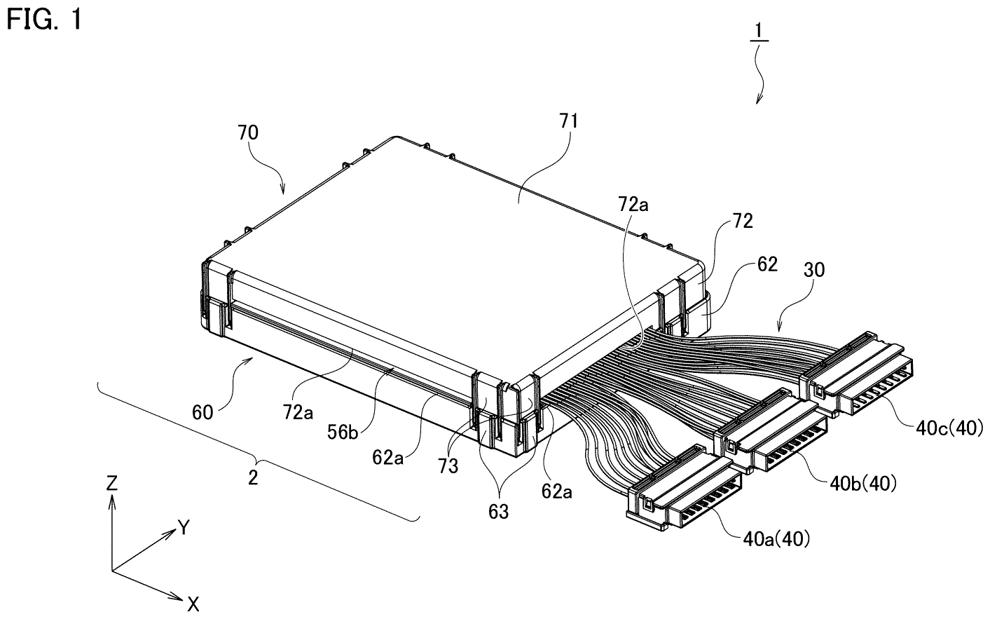

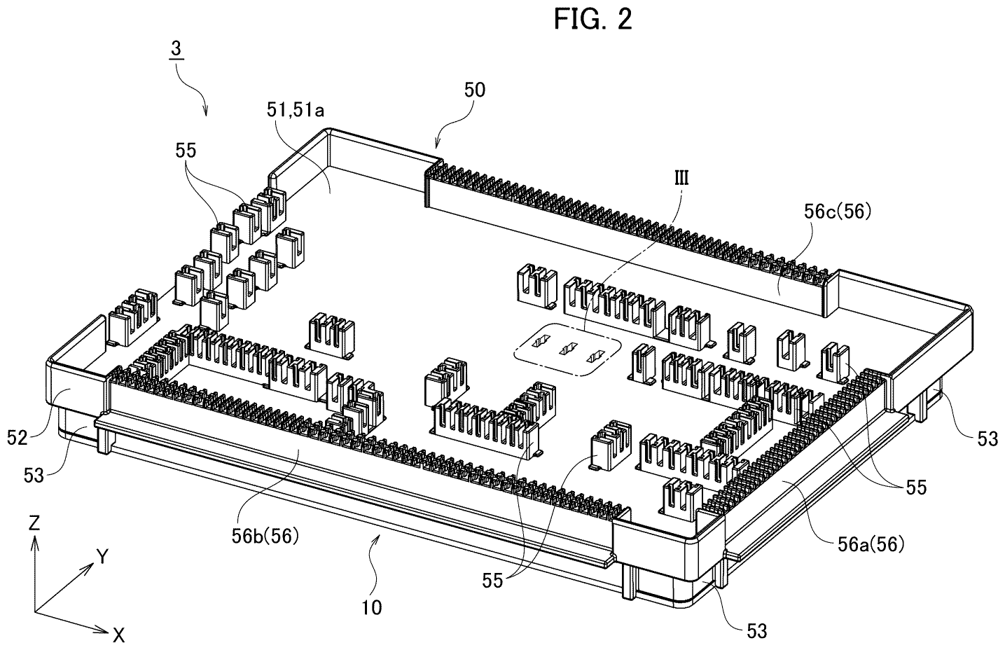

FIG. 1 is a perspective view of an ECU 1 according to one embodiment. FIG. 2 is a perspective view of a circuit unit 3 included in the ECU 1.

The ECU 1 is mounted in a vehicle such as an automobile, and controls various functions. The ECU 1 includes a substrate 10, a plurality of terminals 20, a plurality of electric wires 30, a connector 40, a routing board 50, a first cover 60, and a second cover 70.

Here, in the present embodiment, a unit consisting of the substrate 10, the plurality of terminals 20, a part of the plurality of electric wires 30, the routing board 50, the first cover 60, and the second cover 70 is denoted as “main body 2.” A unit including the substrate 10, the plurality of terminals 20, the plurality of electric wires 30, the connector 40, and the routing board 50 is denoted as “circuit unit 3.”

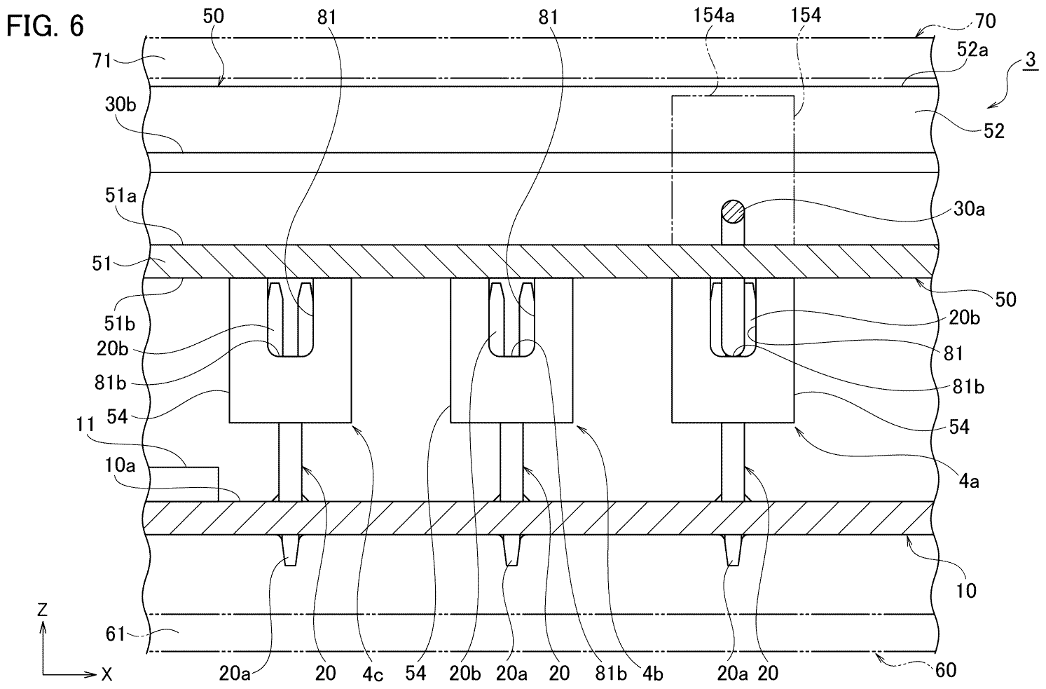

The substrate 10 is, for example, a printed circuit board (PCB) on which a plurality of electronic components 11 (see FIG. 6, for example.) are mounted in advance. Examples of the plurality of electronic components 11 include a CPU (Central Processing Unit) and a memory. In the present embodiment, the substrate 10 is regarded as a substantially rectangular flat plate which is parallel to a virtual XY plane defined by an X direction and a Y direction orthogonal to each other, and which has two ends in the X direction and two ends in the Y direction.

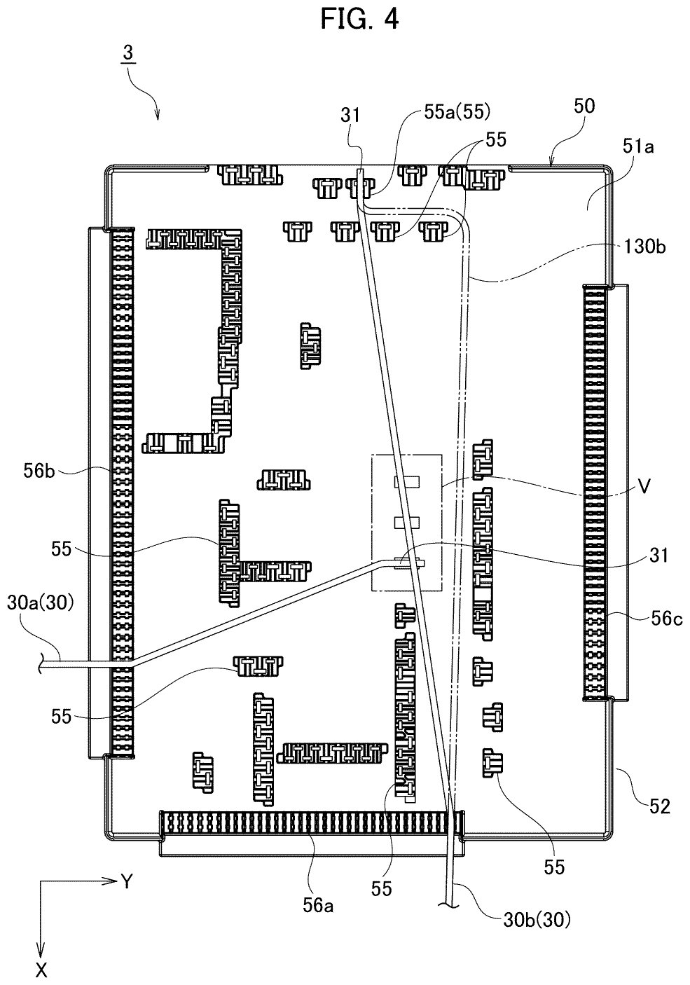

Each of the plurality of terminals 20 electrically connects one of the electric wires 30 to a predetermined circuit on the substrate 10. The terminals 20 are a flat, rod-shaped metal member. Each of the terminals 20 has a first end 20a which is one end, and a second end 20b which is the other end opposite to the first end 20a (see FIG. 6, for example). The first end 20a is connected to a predetermined circuit on the substrate 10. In the present embodiment, since the substrate 10 is regarded as a flat plate parallel to the XY plane, the terminals 20 are each arranged on a mounting surface 10a (see FIG. 6, for example) so as to project in the Z direction orthogonal to both the X and Y directions. The second end 20b connects a first end portion 31 (see FIG. 4) of one of the electric wires 30. The second end 20b includes, for example, two protruding pieces parallel to each other, and a core wire of the electric wires 30 is clamped between the two protruding pieces, so that the first end portion 31 can be easily connected.

In the present embodiment, the terminals 20 are roughly classified into two types, based on the height of the second end 20b when assembled in the circuit unit 3. Specifically, the second end 20b is located between a base 51 of the routing board 50 and the substrate 10 when assembled in the circuit unit 3 in at least one of the terminals 20 (hereinafter referred to as “first terminal”). On the other hand, at least a part of the second end 20b is exposed on the routing surface 51a of the base 51 when assembled in the circuit unit 3 in some of the terminals 20 (hereinafter referred to as a “second terminal”). Note that the terminals 20 illustrated in the drawings correspond to the first terminal. The second terminal is not illustrated for convenience.

The electric wires 30 each electrically connect the connector 40 and one of the terminals 20. The electric wires 30 are electric wires in which a core wire as a conductor, is coated with an insulator. Each of the electric wires 30 has the first end portion 31 which is one end, and a second end portion 32 which is the other end opposite to the first end portion 31. As described above, the first end portion 31 is connected to one of the second ends 20b of the terminals 20. The second end portion 32 is connected to the connector 40. In both of the first end portion 31 and the second end portion 32, a part that actually comes into contact with the second ends 20b or the connector 40 is a core wire portion partially exposed by removing the insulator.

The connector 40 is connected to an external connector (not illustrated) that is provided to an object to which the ECU 1 is attached. In the present embodiment, the ECU 1 includes, as an example, three connectors 40, that is, a first connector 40a, a second connector 40b, and a third connector 40c. The second end portion 32 of each of the electric wires 30 is connected to one of the first connector 40a, the second connector 40b, and the third connector 40c. The connectors 40 are not directly provided on the substrate 10, but are connected to the main body 2 of the ECU 1 only through the electric wire wires 30.

The routing board 50 routes each of the electric wires 30 while connecting the first end portion 31 to the terminals 20 corresponding to each of the electric wires 30 inside the main body 2. The routing board 50 is made of, for example, a synthetic resin, and is a flat member arranged in parallel with the substrate 10. Since the routing board 50 is maintained in a stacked position with respect to the substrate 10, it may also be called a “wiring layer.” The routing board 50 has a base 51, a side wall 52, a pedestal 53, at least one first terminal block 54 (see FIG. 6, for example.), a plurality of second terminal blocks 55, and electric wire inlets 56.

The base 51 is a plate facing the substrate 10 in the Z direction. The planar shape of the base 51 is equivalent to that of the substrate 10. One surface of the base 51 is a routing surface 51a on which a part of each of the electric wires 30 is wired. The other surface of the base 51 is on a side opposite to the routing surface 51a, and is a back surface 51b facing the substrate 10 (See FIG. 6, for example.).

The side wall 52 is continuous with an edge of the base 51, and protrudes in a direction opposite to the side facing the substrate 10 in the Z direction so as to surround a routing space on the routing surface 51a. However, the side wall 52 is not in the form of a frame surrounding entire four sides in the present embodiment, but is continuous with at least one of the electric wire inlets 56.

The pedestal 53 is continuous with the edge of the base 51, and protrudes in the Z direction to be at least partly in contact with an outer edge of the mounting surface 10a of the substrate 10. Thus, a constant distance between the base 51 and the substrate 10 is maintained.

The first terminal blocks 54 and the second terminal blocks 55 support the terminals 20 with the second end 20b thereof being exposed. The arrangement of the terminals 20 depends on the circuit configuration of the mounting surface 10a of the substrate 10. Therefore, the arrangement of the first terminal blocks 54 and the second terminal blocks 55 is also determined based on the circuit configuration of the substrate 10.

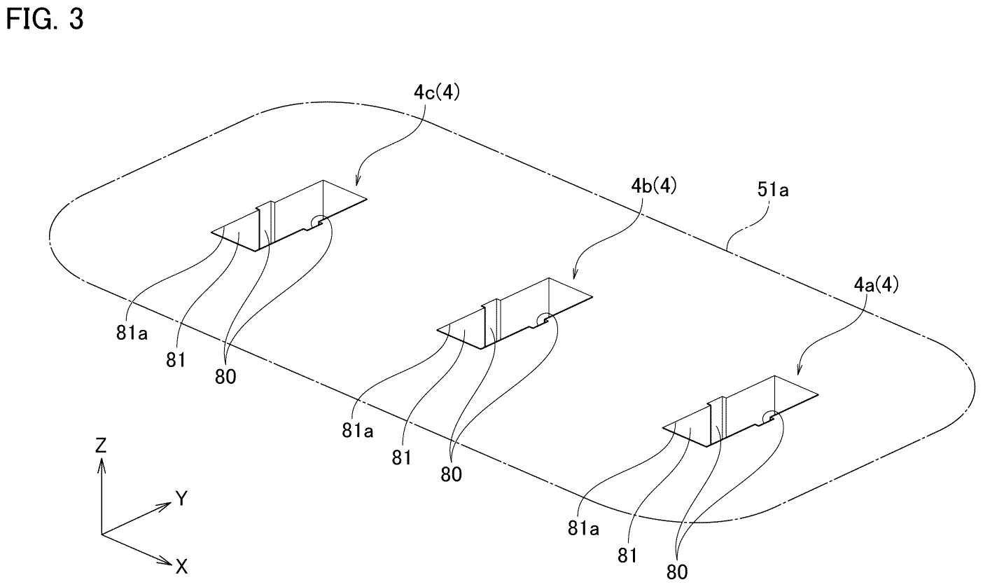

FIG. 3 is an enlarged perspective view of electric wire connections 4 corresponding to part III of FIG. 2. Here, the electric wire connections 4 refer to components in which the electric wires 30 are connected to the second end 20b of the terminals 20 in the first terminal blocks 54 or the second terminal blocks 55.

The first terminal blocks 54 support the second end 20b of the first terminal of the plurality of terminals 20. In the present embodiment, as an example, it is assumed that three terminals 20 are present as the first terminals, and in addition, three first terminal blocks 54 are present to individually support these terminals 20. The first terminal blocks 54 have an opening groove 81 which exposes a part of the second end 20b therein. For each of the electric wires 30, a part of the first end portion 31 is inserted into the opening groove 81 that is predetermined, so that the core wire of the first end portion 31 is connected to the second end 20b. FIG. 3 illustrates a part of the opening grooves 81, and openings 81a of the opening grooves 81, exposed from the routing surface 51a. Hereinafter, the three electric wire connections 4 including the first terminal blocks 54 are referred to as a first electric wire connection 4a, a second electric wire connection 4b, and a third electric wire connection 4c. The first electric wire connection 4a, the second electric wire connection 4b, and the third electric wire connection 4c are lined up in a direction opposite to the X direction. The specific configuration of the electric wire connections 4 including the first terminal blocks 54 will be described in detail below.

The second terminal blocks 55 support a second end of a second terminal (not illustrated) among the terminals 20. As will be described later, the first terminal blocks 54 are provided on the back surface 51b of the base 51, while the second terminal blocks 55 are provided on the routing surface 51a of the base 51. The basic shape of the second terminal blocks 55 itself is the same as that of the first terminal blocks 54. Specifically, the second terminal blocks 55 supporting the second end of one of the terminals 20 have a shape in which the first terminal blocks 54 are inverted in the Z direction with respect to the base 51. The second terminal blocks 55 may have a shape in which a plurality of second terminal blocks 55 supporting the second end of one of the terminals 20 are integrated in parallel and continuously.

In the present embodiment, three first terminals are present, and terminals among the plurality of terminals 20 other than first terminals are second terminals. However, among the plurality of terminals 20, the number of the first terminals may be larger than the number of the second terminals. Furthermore, all of the plurality of terminals 20 may be first terminals. That is, the presence of the second terminals is not essential. Therefore, when all of the plurality of terminals 20 are the first terminals, all of the plurality of terminal blocks present in the routing board 50 become the first terminal blocks 54.

The electric wire inlets 56 introduce the electric wires 30 onto the routing surface 51a of the base 51 from the outside of the routing board 50 while supporting a part of the electric wires 30. At least one of the electric wire inlets 56 is provided as a convex portion at an outer edge of the routing board 50 and on the routing surface 51a. In the present embodiment, as an example, three electric wire inlets 56 are present: a first electric wire inlet 56a extending in the Y direction, and a second electric wire inlet 56b and a third electric wire inlet 56c, each extending in the X direction. When routing the electric wires 30, not necessarily all of the electric wire inlets 56 are used. FIG. 1 illustrates, as an example, a configuration in which all the electric wires 30 are pulled into the body 2 from the connector 40 only through the first electric wire inlet 56a.

The first cover 60 and the second cover 70 are combined with each other to accommodate at least the substrate 10, the plurality of terminals 20, and the routing board 50 included in the circuit unit 3. The first cover 60 and the second cover 70 may be made of a synthetic resin or metal, for example.

The first cover 60 is a cover to be assembled from a side facing the substrate 10. The first cover 60 has a first flat plate 61 (see FIG. 6) covering the substrate 10 and a first frame 62 continuous with an edge of the first flat plate 61. The first frame 62 projects in the Z direction in which is the first frame 62 is assembled with respect to the second cover 70, so as to surround the substrate 10, for example. A part of a first tip edge 62a of the first frame 62 is close to the electric wire inlets 56 of the routing board 50 in a non-contact manner.

The second cover 70 is a cover to be assembled from a side facing the routing surface 51a of the routing board 50. The second cover 70 has a second flat plate 71 (see FIG. 6) covering the routing board 50, and a second frame 72 continuous with an edge of the second flat plate 71. The second frame 72 projects in a direction opposite to the Z direction, which is the direction to be assembled with respect to the first cover 60, so as to surround at least a part of the routing board 50, for example. A part of a second tip edge 72a of the second frame 72 is close to the electric wire inlet 56 of the routing board 50 in a non-contact manner. A part of an area between the first tip edge 62a of the first frame 62 of the first cover 60 and the second tip edge 72a of the second frame portion 72 of the second cover 70 is an open area through which the plurality of electric wires 30 pass inside and outside the main body 2.

The first cover 60 has a plurality of first locking portions 63 in the first frame 62. On the other hand, the second cover 70 has a plurality of second locking portions 73 in the second frame 72. The second cover 70 is combined with the first cover 60 by engaging the second locking portions 73 with the first locking portions 63.

Next, a specific configuration of the electric wire connections 4 including the first terminal blocks 54 will be described.

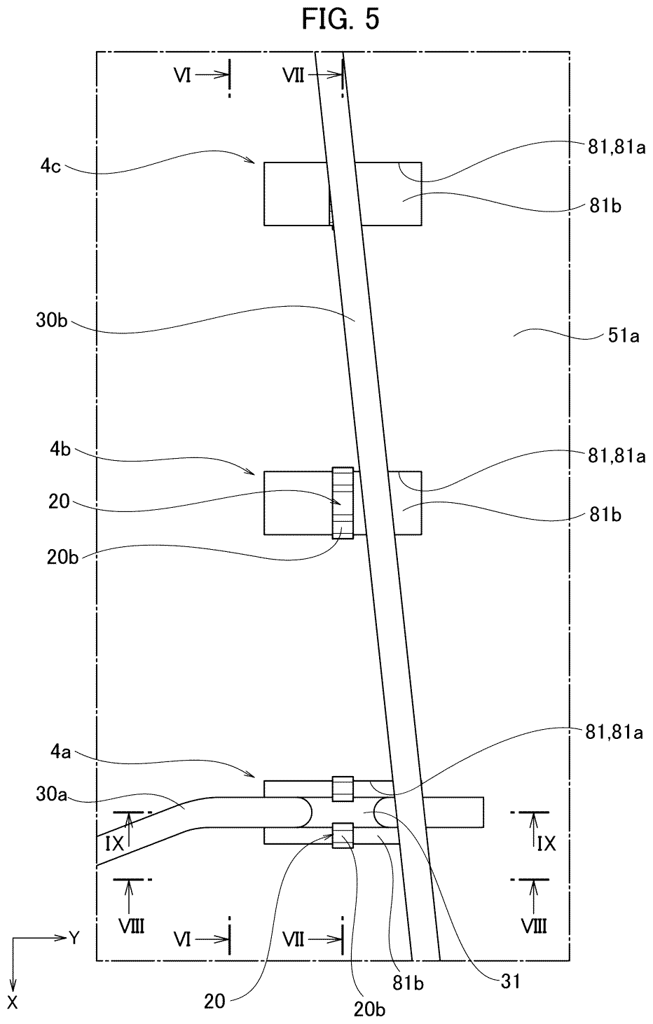

FIG. 4 is a plan view of the circuit unit 3 including an example of wiring on the routing board 50. FIG. 5 is an enlarged plan view of the electric wire connections 4 including the first terminal blocks 54 corresponding to part V in FIG. 4.

Here, although a large number of the electric wires 30 can actually be wired in the routing board 50, only two electric wires 30, the first electric wire 30a and the second electric wire 30b, will be exemplified below for the sake of simplicity.

The first electric wire 30a is an example of the electric wires 30 pulled into the main body 2 from a connector (not illustrated) similar to the connector 40 through the second electric wire inlet 56b. The first electric wire 30a is linearly wired from the second electric wire inlet 56b toward the first electric wire connection 4a on the routing surface 51a, for example, passing through gaps in the plurality of second terminal blocks 55. The first end portion 31 of the first electric wire 30a is connected to the second end 20b of the terminals 20 located in the first electric wire connection 4a.

The second electric wire 30b is an example of the electric wires 30 pulled into the main body 2 from the connector 40 through the first electric wire inlet 56a. The second electric wire 30b is linearly routed from the first electric wire inlet 56a to the second end 20b of the terminals 20 supported by one of the second terminal blocks 55, for example, passing through gaps in the plurality of second terminal blocks 55 on the routing surface 51a. Hereinafter, the second terminal block 55 supporting the second end 20b to which the first end portion 31 of the second electric wire 30b is connected is referred to as a “connection terminal block 55a” for convenience. The connection terminal block 55a is provided in the vicinity of another side wall 52 opposed in the X direction to the side wall 52 in which the first electric wire inlet 56a is provided.

The second electric wire 30b passes through an upper portion of the openings 81a corresponding to each of the first electric wire connection 4a, the second electric wire connection 4b, and the third electric wire connection 4c. The second electric wire 30b passes above the first electric wire 30a connected to the first electric wire connection 4a. Here, “above” with respect to each member refers to an area corresponding to an upper side when the routing surface 51a is a horizontal plane, and the normal direction of the routing surface 51a aligned with the Z direction is from bottom to top.

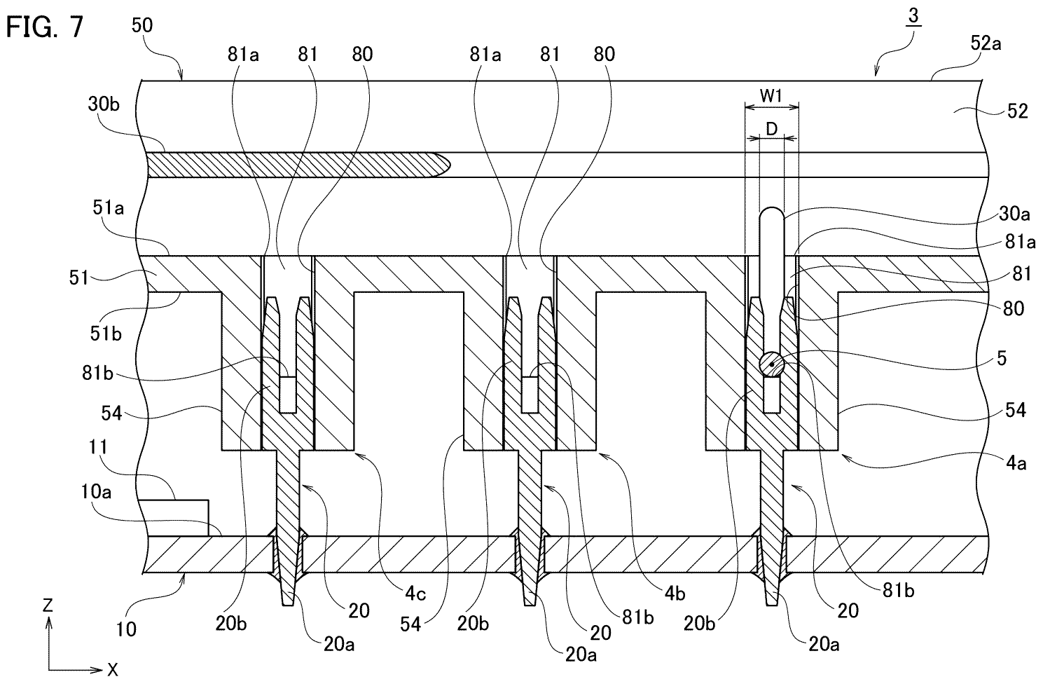

FIGS. 6 and 7 are views of the first electric wire connection 4a, the second electric wire connection 4b, and the third electric wire connection 4c as viewed in the Y direction. FIG. 6 is a side view of the electric wire connections 4 corresponding to a cross section VI-VI in FIG. 5. FIG. 7 is a cross-sectional view of the electric wire connections 4 corresponding to a cross section VII-VII in FIG. 5. The cross section in FIG. 7 is in an XZ plane passing through an intermediate position in a thickness direction corresponding to the Y direction of the terminals 20 supported by the first terminal blocks 54.

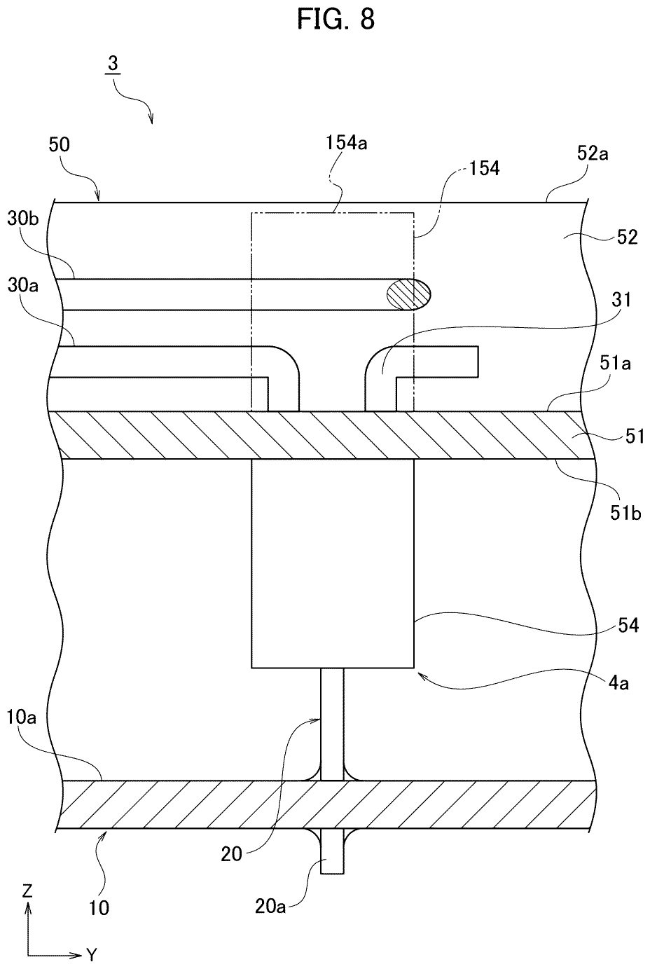

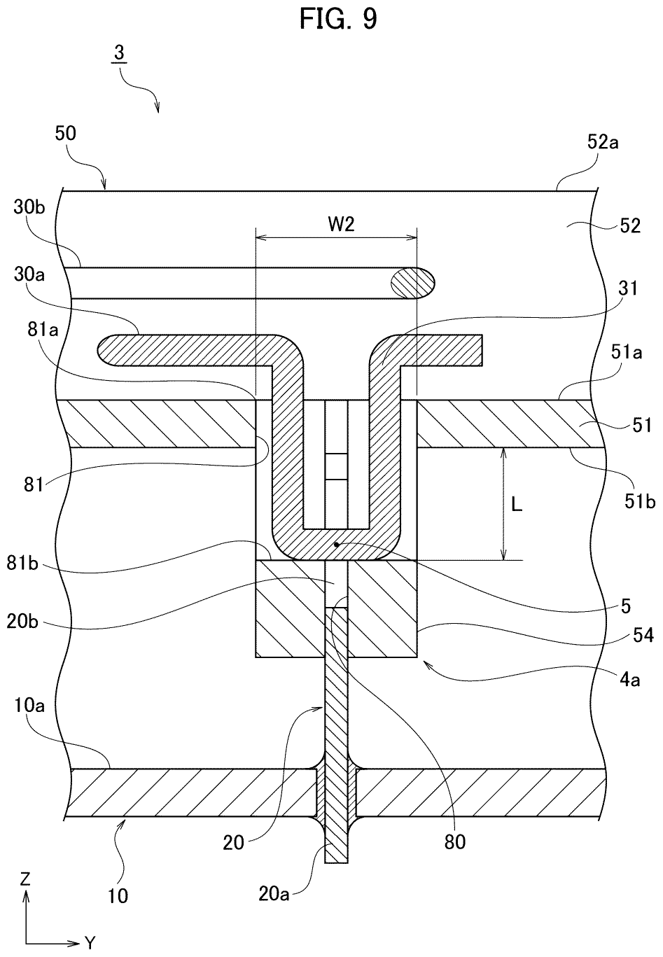

FIGS. 8 and 9 are views of the first electric wire connection 4a viewed in the negative X direction. FIG. 8 is a side view of the first electric wire connection 4a corresponding to a cross section VIII-VIII in FIG. 5. FIG. 9 is a cross-sectional view of the first electric wire connection 4a corresponding to a cross section IX-IX in FIG. 5. The cross section in FIG. 9 is in the YZ plane passing through an intermediate position in a width direction corresponding to the X direction of the terminals 20 supported by the first terminal blocks 54.

The three electric wire connections 4 including the first terminal blocks 54 have the same configuration. Therefore, the first electric wire connection 4a will be mainly described with respect to the shape or the like.

First, the second end 20b of the terminals 20 as the first terminals connects the electric wires 30 by clamping a core wire of the electric wires 30 between the two protruding pieces as described above. Hereinafter, the position in which the second end 20b clamps and connects the first electric wire 30a is defined as a “connection point 5,” as illustrated in FIGS. 7 and 9. The second end 20b is located between the base 51 and the substrate 10, so that the connection point 5 is located close to the substrate 10 relative to the position of the base 51.

The first terminal blocks 54 are provided for each of the terminals 20 in the present embodiment, and therefore, three first terminal blocks 54 are present for the first electric wire connection 4a, the second electric wire connection 4b, and the third wire connection 4c. As in the example of the second terminal blocks 55 described above, the first terminal blocks 54 may have a shape such that the three first terminal blocks 54 supporting the second end 20b of each of the terminals 20 are integrated in parallel and continuously.

The overall schematic shape of the first terminal blocks 54 is a cuboid with one end continuous with the back surface 51b of the base 51. The first terminal blocks 54 have a terminal through-hole 80 and the opening groove 81.

The terminal through-hole 80 accommodates the second end 20b of each of the terminals 20. The terminal through-hole 80 is penetrating in the Z direction, a direction in which the base 51 faces the substrate 10. One opening of the terminal through-hole 80 is located at a tip of the first terminal block 54 facing the substrate 10. The other opening of the terminal through-hole 80 is located at a bottom surface 81b of the opening groove 81. However, a part of a wall defining the terminal through-hole 80 may be a pair of grooves extending from the bottom surface 81b to the opening 81a in the Z direction and exposed from the routing surface 51a. In other words, if exposed ends of the grooves are also regarded as a part of the opening 81a, the part of the opening 81a can be regarded as facing each of the terminals 20 in the Z direction. In the present embodiment, the direction in which the second end 20b clamps the first electric wire 30a (Hereinafter referred to as a “clamping direction.”) is in the X direction, so that the pair of grooves in which a part of the wall defining the terminal through-hole 80 is exposed from the routing surface 51a also face each other in the X direction.

The opening groove 81 has at least the opening 81a formed as a part of the base 51 on the routing surface 51a, and a bottom surface 81b separated from the opening 81a toward the substrate 10, allowing the first end portion 31 of the first electric wire 30a to be introduced from the opening 81a. The opening groove 81 communicates with the terminal through-hole 80, and exposes a part of the second end 20b of the terminals 20 therein. In order to satisfy conditions that the first end portion 31 is introduced from the opening 81a, and the second end 20b clamps and connects the introduced first end portion 31, a first width W1 of the opening 81a in a direction along a clamping direction is set larger than a dimension of an outer diameter D of the first electric wire 30a. On the other hand, a second width W2 in a direction orthogonal to the first width W1 of the opening 81a is set larger than the first width W1 to the extent that a tip of the first end portion 31 can be exposed on the routing surface 51a as in the present embodiment.

The bottom surface 81b of the opening groove 81 is substantially parallel to the routing surface 51a, and is set at a position at a distance L from the back surface 51b of the base 51, for example. The distance L may be set in advance so that the connection point 5 is set at a desired position when the first end portion 31 of the first electric wire 30a introduced into the opening groove 81 is in contact with the bottom surface 81b. It should be noted that the opening groove 81 may be opened from the back surface 51b to the bottom surface 81b of the base 51 so as to be opened to a spatial region between the base 51 and the substrate 10.

Next, the effect of the ECU 1 will be described.

The ECU 1 includes the substrate 10 on which the electronic components 11 are mounted, the plurality of terminals 20 having the first ends 20a connected to the substrate 10, and the plurality of electric wires 30 having the first end portion 31 connected to the second end 20b of the terminals 20 on an opposite side of the first ends 20a. The ECU 1 also includes the routing board 50 having the base 51 in a shape of a plate, arranged in parallel with the substrate 10. The routing board 50 routes the plurality of electric wires 30 introduced from the outside on the routing surface 51a of the base 51 opposite to the back surface 51b facing the substrate 10. The second end 20b of at least one of the terminals 20 is located between the base 51 and the substrate 10. The base 51 has an opening 81a partially facing the terminals 20 having the second end 20b located between the base 51 and the substrate 10 and introducing the electric wires 30.

Here, for comparison, it is assumed that a virtual terminal block 154 equivalent to the second terminal block 55 is provided at the position of the first electric wire connection 4a instead of the first terminal block 54 in FIGS. 6 and 8. In other words, the virtual terminal block 154 supports a second terminal at least partially exposed on the routing surface 51a of the base 51. The height of a tip face 154a in the Z direction of the virtual terminal block 154 can be set equal to the position of a tip edge 52a of the side wall 52 of the routing board 50.

According to the comparative example in which the virtual terminal block 154 is present, the first electric wire 30a can be wired in a wiring path equivalent to the above example in which the virtual terminal block 154 is not present, by connecting the first end portion 31 to the second end 20b supported by the virtual terminal block 154. However, the second electric wire 30b cannot pass through an upper portion of the opening 81a included in the first electric wire connection 4a due to the virtual terminal block 154 present at the position of the first electric wire connection 4a. Therefore, as illustrated in FIG. 4, a virtual electric wire 130b in place of the second electric wire 30b is routed on a wiring path that avoids not only the virtual terminal block 154 but also a plurality of the second terminal blocks 55. In other words, the wiring path of the virtual electric wire 130b is assumed to be more complicated than that of the second electric wire 30b. Moreover, the length of the virtual electric wire 130b is assumed to be longer than that of the second electric wire 30b.

In the ECU 1 according to the present embodiment, for some of the terminals 20, the second end 20b is shaped to be located between the base 51 and the substrate 10, so that the position of the connection point 5 connecting to the first end portion of the desired one of the electric wires 30 is not set on the routing surface 51a. Therefore, according to the ECU 1, when some of the electric wires 30 such as the second electric wire 30b should be wired on a simple linear path, for example, the second end 20b of the terminals 20 can be prevented from being arranged at a position crossing the wiring path. In addition, although the wiring path is set on the routing surface 51a, the fact that the second end 20b is prevented from being arranged at a position crossing the wiring path means that the second terminal block 55 need not be arranged on the routing surface 51a. Therefore, as illustrated in FIGS. 4 and 5, the second electric wire 30b is less likely to interfere with the electric wires 30 such as the first electric wire 30a connected to one of the terminals 20, or with a terminal block on the routing surface 51a such as the second terminal block 55, degrees of freedom for wiring the electric wires 30 can be increased. In particular, instead of the examples illustrated in the drawings, degrees of freedom for wiring the electric wires 30 can be further improved if the second end 20b is arranged between the base 51 and the substrate 10 in many of the terminals 20.

As described above, according to the present embodiment, it is possible to provide the ECU 1 which increases the degrees of freedom for wiring therein.

According to the ECU 1, the wiring path is simplified for each of the electric wires 30 by increasing the degrees of freedom for wiring, wire saving of the plurality of electric wires 30 is possible, and the main body 2 can be miniaturized or reduced in weight by increasing the wiring space on the routing board 50.

In addition, in the ECU 1, the routing board 50 may have a plurality of terminal blocks which support the second end 20b with a part thereof exposed. The terminal blocks which support the second end 20b located between the base 51 and the substrate 10 may be provided on the back surface 51b of the base 51.

In the above example, the terminal block which supports the second end 20b located between the base 51 and the substrate 10 is the first terminal block 54 among the plurality of terminal blocks. On the other hand, the terminal blocks other than the first terminal blocks 54 are the second terminal blocks 55.

According to the ECU 1, the terminals 20 having the second end 20b located between the base 51 and the substrate 10 are also supported by the first terminal blocks 54, so that the connection stability between the terminals 20 and the electric wires 30 can be prevented from deteriorating.

Furthermore, the ECU 1 may include the connectors 40 to which the second end portion 32 opposite to the first end portion 31 of each of the electric wires 30 is connected.

In this ECU 1, the connectors 40 are only connected to the main body 2 via the plurality of electric wires 30, so that positions of the connectors 40 can be freely changed relative to the main body 2. Therefore, according to the ECU 1, it is possible to avoid, for example, the occurrence of troubles such as reduced space in a passenger compartment due to bulging of external electric wires around the main body 2.

While certain embodiments have been described, these embodiments have been presented by way of example only, and are not intended to limit the scope of the inventions. Indeed, the novel embodiments described herein may be embodied in a variety of other forms; furthermore, various omissions, substitutions, and changes in the form of the embodiments described herein may be made without departing from the spirit of the inventions. The accompanying claims and their equivalents are intended to cover such forms or modifications as would fall within the scope and spirit of the inventions.

1. An electronic control unit comprising:
a substrate on which electronic components are mounted;
a plurality of terminals having a first end connected to the substrate;
a plurality of electric wires having a first end portion connected to one of the second ends of the plurality of terminals on an opposite side to the first end; and
a routing board having a base in a shape of a plate, arranged in parallel with the substrate;
wherein:
the routing board routes the plurality of electric wires introduced from outside on a routing surface of the base opposite to a back surface facing the substrate;
the second ends of at least one of the terminals are located between the base and the substrate; and
the base has an opening partially facing the terminals having the second ends located between the base and the substrate and introducing the electric wires.

2. The electronic control unit according to claim 1, wherein
the routing board has a plurality of terminal blocks which support the second ends with a part thereof exposed; and
the terminal blocks which support the second ends located between the base and the substrate is provided on the back surface of the base.

3. The electronic control unit according to claim 1, further comprising connectors to which a second end portion opposite to the first end portion of each of the electric wires is connected.
